(19) United States
(12) Patent Application Publication
(10) Pub. No.: US 2010/0144124 A1
(43) Pub. Date: Jun. 10, 2010

(54) METHOD OF GROWING PURE Ge THIN FILM WITH LOW THREADING DISLOCATION DENSITY

(75) Inventors: Sang Hoon KIM, Seoul (KR); Dong Woo Suh, Daejeon (KR); Ji Ho Joo, Gyeonggi-do (KR); Gyung Ock Kim, Seoul (KR); Hyun Tak Kim, Daejeon (KR)

Correspondence Address: RABIN & Berdo, PC, 1101 14TH STREET, NW, SUITE 500, WASHINGTON, DC, 20005, US

(73) Assignee: ELECTRONICS AND TELECOMMUNICATIONS RESEARCH INSTITUTE, Daejeon (KR)

(21) Appl. No.: 12/536,475

(22) Filed: Aug. 5, 2009

(30) Foreign Application Priority Data
Dec. 5, 2008 (KR) 10-2008-0123326

(51) Int. Cl. H01L 21/205

(52) U.S. Cl. 438/478; 257/E21.101

(57) ABSTRACT

Provided is a method of growing a pure germanium (Ge) thin film with low threading dislocation density using reduced pressure chemical vapor deposition (RPCVD), which includes growing a Ge thin film on a silicon (Si) substrate at a low temperature, performing real-time annealing for a short period of time, and growing the annealed Ge thin film at a high temperature. The grown Ge single crystal thin film can overcome conventional problems of generation of a Si—Ge layer due to Si diffusion, and propagation of misfit dislocation to a high-temperature Ge thin film.

### CROSS-REFERENCE TO RELATED APPLICATION

This application claims priority to and the benefit of Korean Patent Application No. 10-2008-0123326, filed Dec. 5, 2008, the disclosure of which is incorporated herein by reference in its entirety.

### BACKGROUND

1. Field of the Invention

The present invention relates to a pure germanium (Ge) single crystal layer, which is grown on a silicon substrate, and more particularly, to a method of forming a stress relaxed Ge single crystal thin film, low threading dislocation density and good surface roughness using reduced pressure chemical vapor deposition (RPCVD).

2. Discussion of Related Art

Development of novel devices using heterojunctions of silicon (Si) and silicon-germanium (Si—Ge) or germanium (Ge) has been conducted for several decades. These devices generally utilize a difference in band-gap energy between Si and Ge, or high-mobility characteristics generated due to stress applied according to a difference of lattice constants between Si and Ge.

In recent times, research into developing a processing technique to integrate Ge—CMOS with Si—CMOS and to fabricate a detector device for optical communication operating in an optical absorption wavelength range (1.3 to 1.55 μm) of band-gap energy (0.67 eV) of Ge, has been actively progressing. Before this, research into growth of a pure Ge thin film or a SiGe relaxed buffer layer on the silicon substrate is necessary, various results of which are being reported.

A lattice strain f, which is a critical variant of a hetero structure of Si and Ge can be defined by the following expression:

f=(a_{layer}−a_{sub})/a_{sub}

Here, a_{sub} is a lattice constant of a substrate and a_{layer} is a lattice constant of a deposited layer. f has a value of 4.2% for Si and Ge. This structure has a different equilibrium critical thickness t_{c} at a different Ge deposition temperature, and t_{c} decreases as the deposition temperature increases. The lattice structure having a thickness of t_{c} or less is a perfect square, which is present in a stable phase through elastic deformation, while the lattice structure has a thickness of more than t_{c}, an energy required to generate misfit dislocation is smaller than an elastic deformation energy of the deposited Ge, and thus stress relaxation occurs due to generation of the misfit dislocation. The t_{c} values are dependant upon nucleation sites or propagation mechanisms of dislocation as well as the deposition temperature.

Accordingly, the growth of the Ge single crystal thin film should satisfy various conditions, including sufficient stress relaxation due to the misfit dislocation, smooth surface of the thin film, which is because there are many limits to device manufacturing processes for rough rippled surfaces, and non-propagation of threading dislocation generated by stress relaxation to a surface of the Ge thin film. The threading dislocation propagated to the surface may cause defects of a thin film to be formed thereon, deteriorating device's characteristics or causing leakage current. Finally, for commercialization, a processing time for forming the Ge single crystal thin film needs to be shortened.

Among conventional arts, as shown in FIG. 1A, a method of growing Ge 110 and 120 using ultra-high vacuum chemical vapor deposition (UHVCVD) in two steps at low and high temperatures, and annealing the grown Ge 400 for 10 cycles under conditions of 780° C. for 10 minutes, and 900° C. for 10 minutes has been reported as a growth method for a Ge single crystal, which is capable of satisfying the above-mentioned conditions and has good characteristics. However, since this method requires high-priced UHVCVD equipment, and annealing cannot be performed in UHVCVD, rapid thermal processing (RTP) should be added, which is a time-consuming process taking almost 4 hours. Further, due to interdiffusion between Si and Ge caused by high-temperature annealing, a Si—Ge layer is formed at an interface, affecting a change in band-gap and the device's characteristics.

FIG. 1B is a transmission electron microscope (TEM) photograph of the Ge single crystal thin film according to the conventional art. As shown in FIG. 1B, misfit dislocation widely propagates to the low-temperature Ge layer 110 and the high-temperature Ge layer 120. The misfit dislocation may be a cause of deterioration of the device's characteristics during the fabrication of the device.

The present inventors have found that generation of upper threading dislocation is inhibited by sufficiently relaxing the stress of the low-temperature thin film when real-time annealing is performed for a very short period of time between low and high temperature growth steps using a two-step growth method performed at high and low temperatures in order to reduce defects generally generated due to the lattice constant difference between Si and Ge and to optimize a state of surface roughness, and thus the present invention was completed.

### SUMMARY OF THE INVENTION

The present invention is directed to a method of growing pure germanium (Ge) single crystal with thin film low threading dislocation density and a smooth surface on a silicon substrate.

One aspect of the present invention provides a method of growing a germanium (Ge) single crystal thin film with low threading dislocation density using reduced pressure chemical vapor deposition (RPCVD), including: growing a Ge thin film on a silicon (Si) substrate at a low temperature; performing real-time annealing for a short period of time; and growing the annealed Ge thin film at a high temperature.

Another aspect of the present invention provides a method of growing a Ge single crystal thin film with low threading dislocation density using RPCVD, including: growing a Ge thin film on a Si substrate at a low temperature; performing real-time annealing for a short period of time; growing a Si—Ge thin layer after real-time annealing; and growing the annealed Ge thin film at a high temperature on the Si—Ge thin layer.

The low-temperature Ge thin film may be grown under the conditions of a temperature of 300 to 500° C. and a pressure of 30 to 80 Torr. Here, the low-temperature Ge thin film may be grown to a thickness of 80 to 120 nm.

The real-time annealing may be performed for 5 to 20 minutes by stopping injection of a Ge source gas, injecting only a carrier gas, and increasing a temperature to 850 to 900° C. at a pressure of 30 to 80 Torr. Here, the temperature increasing and decreasing rates may be 200° C. per minute.

The high-temperature Ge thin film may be grown under the conditions of a temperature of 600 to 800° C. and a pressure of 30 to 80 Torr. Here, the high-temperature Ge thin film may be grown to a thickness of 500 to 1500 nm.

In the second aspect, the Si—Ge thin film may be grown to a thickness of 50 to 100 nm under the conditions of a temperature of 600 to 650° C. and a pressure of 30 to 80 Torr. While growing the Si—Ge thin film, the Ge content may linearly increase from 80 to 85 at % to 100 at %.

The source gas used for the low- and high-temperature Ge thin films may be GeH₄ gas diluted to 10 to 30 vol % with hydrogen gas, and the carrier gas may be hydrogen gas. The source gases used for the Si—Ge thin film are SiH₄ and GeH₄ gases, and the Ge content may be controlled by a ratio of these gases.

### BRIEF DESCRIPTION OF THE DRAWINGS

The above and other objects, features and advantages of the present invention will become more apparent to those of ordinary skill in the art by describing in detail preferred embodiments thereof with reference to the attached drawings in which:

FIG. 1A is a cross-sectional view of the structure of a conventional Ge single crystal thin film formed using UHVCVD;

FIG. 1B is a TEM photograph of the conventional Ge single crystal thin film formed using UHVCVD;

FIG. 2 is cross-sectional views illustrating a method of forming a Ge single crystal thin film using RPCVD according to an exemplary embodiment of the present invention;

FIG. 3 is cross-sectional views illustrating a method of forming a Ge single crystal thin film using RPCVD according to another exemplary embodiment of the present invention;

FIG. 4 is a SIMS profile showing Ge concentrations after real-time annealing a Ge thin film grown at a low temperature according to an exemplary embodiment of the present invention;

FIG. 5 is a SIMS profile showing differences between the conventional Ge single crystal thin film and the Ge single crystal thin film according to an exemplary embodiment of the present invention;

FIG. 6 is a TEM photograph of a Ge single crystal thin film formed using RPCVD according to an exemplary embodiment of the present invention; and

FIG. 7 is an optical microscope photograph after Secco-etching for the purpose of measuring threading dislocation density of the Ge single crystal thin film formed using RPCVD according to an exemplary embodiment of the present invention.

### DETAILED DESCRIPTION OF EXEMPLARY EMBODIMENTS

Hereinafter, the present invention will be described with reference to the accompanying drawings in detail. This invention may, however, be embodied in different forms and should not be construed as limited to the embodiments set forth herein. Rather, these embodiments are provided so that this disclosure will be thorough and complete, and will fully convey the scope of the invention to those skilled in the art. Like numbers refer to like elements throughout the specification.

FIG. 2 is cross-sectional views illustrating a method of forming a germanium (Ge) single crystal thin film using reduced pressure chemical vapor deposition (RPCVD) according to an exemplary embodiment of the present invention.

Referring to FIG. 2, a Ge thin film 210 is grown on a silicon substrate 200 using RPCVD at a low temperature. Here, the temperature may range from 300 to 500° C., and the pressure may range from 30 to 80 Torr. When the temperature is over 500° C., the Ge thin film may not be evenly grown due to surface tension, and its surface may become very rough due to 3-D growth in a semi-circular shape.

A source gas for depositing the Ge thin film 210 may be GeH₄ gas, which is diluted to 10 to 30 volume % with hydrogen, and a carrier gas may be hydrogen gas. A flow rate of the source gas may range from 150 to 250 sccm, and a flow rate of the carrier gas may range from 10 to 30 slm.

The low-temperature Ge thin film 210 may have a thickness of 80 to 120 nm. Beyond this range, the surface of the thin film may become very rough due to the influence of Ge segregation during annealing.

After growing the Ge thin film 210 at a low temperature, real-time annealing(500) is performed for a short period of time using RPCVD. Here, injection of the source gas is stopped, and the temperature increases to 850 to 900° C. to perform annealing for 5 to 20 minutes. At this time, a temperature increasing rate is 200° C. per minute, and a temperature decreasing rate after annealing is also 200° C. per minute.

When the Ge thin film is grown at a high temperature immediately after being grown at a low temperature, misfit dislocation and threading dislocation are generated due to residual stress on the low-temperature Ge thin film. This problem can be overcome by sufficiently relaxing stress to remove a cause of the stress during the Ge growth at the high temperature and inhibit the generation of dislocation through real-time annealing.

These conditions for real-time annealing are optimum conditions determined through experiments, and thus beyond these conditions, the surface of the thin film may become rough due to Ge segregation.

After real-time annealing, the Ge thin film 220 is grown at a high temperature using RPCVD. Here, the temperature may range from 600 to 800° C., and the pressure may range from 30 to 80 Torr. A source gas and a carrier gas are the same as those for the growth of the low-temperature Ge thin film, and a flow rate of the source gas may range from 20 to 50 sccm, and a flow rate of the carrier gas may range from 10 to 30 slm.

The high-temperature Ge thin film 220 may have a thickness of 500 to 1500 nm.

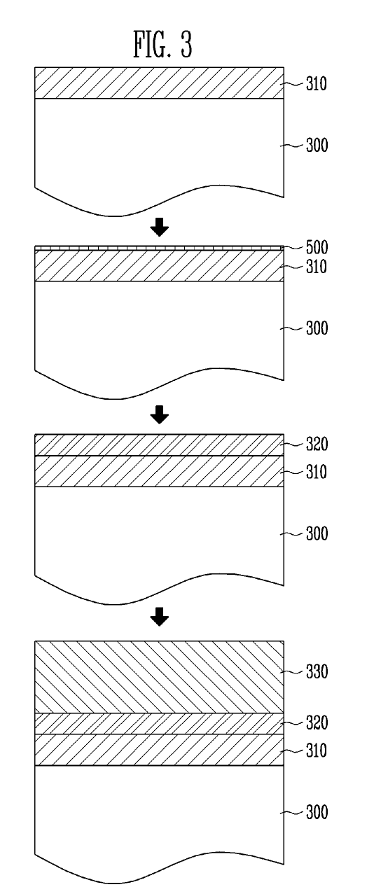

FIG. 3 is cross-sectional views illustrating a method of forming a Ge single crystal thin film using RPCVD according to another exemplary embodiment of the present invention.

Referring to FIG. 3, a low-temperature Ge thin film 310 is grown on a silicon substrate 300, and then real-time annealing and growth of a high-temperature Ge thin film 330 are performed in the same manner as described with reference to FIG. 2. Meanwhile, after real-time annealing(500), growing a Si—Ge thin film 320 on the low-temperature Ge thin film 310 is further included.

The low temperature Ge thin film 310 grown over the silicon substrate is changed into a Si—Ge thin film having a Ge content of 80 to 85 at % on its surface by gradually increasing the Ge content through annealing. Thus, after annealing the low-temperature Ge thin film, when the Si—Ge thin film 320 linearly increasing the Ge content from 80 to 85 at % to 100 at % is deposited over the low-temperature Ge thin film, the cause of stress is removed to further inhibit the generation of dislocation.

The Si—Ge thin film 320 is grown at a temperature of 600 to 650° C. and a pressure of 30 to 80 Torr, and the Ge content is controlled by a ratio of SiH₄ and GeH₄ gases. Here, the Si—Ge thin film may be formed to a thickness of 100 nm or less, and preferably ranging from 50 to 100 nm.

### EXAMPLE 1

In RPCVD, GeH₄ diluted to 20 vol % with hydrogen was injected to a silicon substrate at a flow rate of 200 sccm under the conditions of 400° C. 15 and 30 torr, and hydrogen gas was injected at a flow rate of 20 slm to grow a Ge thin film to a thickness of 100 nm. Subsequently, in RPCVD, the injection of the GeH₄ gas was stopped, a temperature was increased to 875° C. at a rate of 200° C. per minute, and annealing was performed for 10 minutes. After annealing, the temperature was decreased at the same rate at which it was increased, 200° C. per minute, and the GeH₄ gas was injected at a flow rate of 40 sccm under the conditions of 700° C. and 80 torr to grow the Ge thin film to a thickness of 1400 nm.

### EXPERIMENTAL EXAMPLE

Analysis of Ge Concentration after Annealing

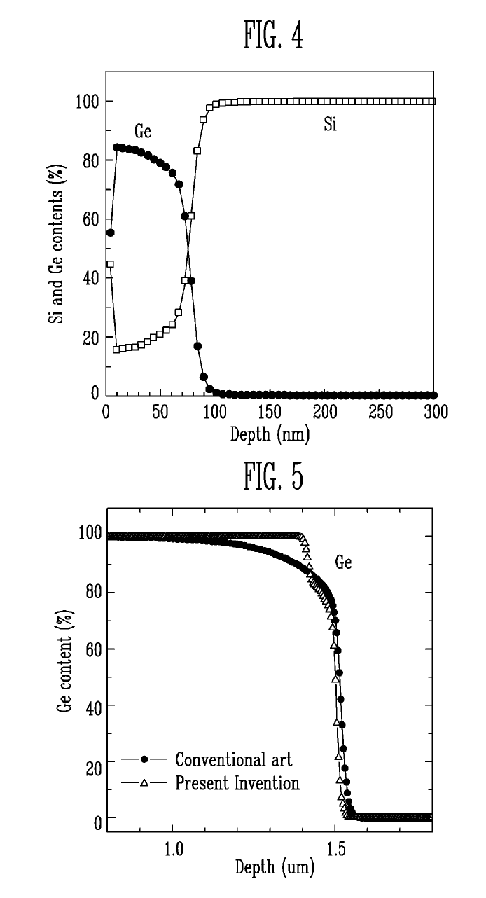

After real-time annealing the Ge thin film having a thickness of 100 nm grown at a low temperature according to Example 1, the Ge concentration was obtained through SIMS analysis, and the result is shown in FIG. 4.

As shown in FIG. 4, the low-temperature Ge thin film grown over the silicon substrate was changed into a Si—Ge thin film (Si_{0.16}Ge_{0.84}) having a Ge content of 84 at % on its surface by gradually increasing the Ge content through annealing.

Analysis of Ge Concentration of Ge Single Crystal Thin Film

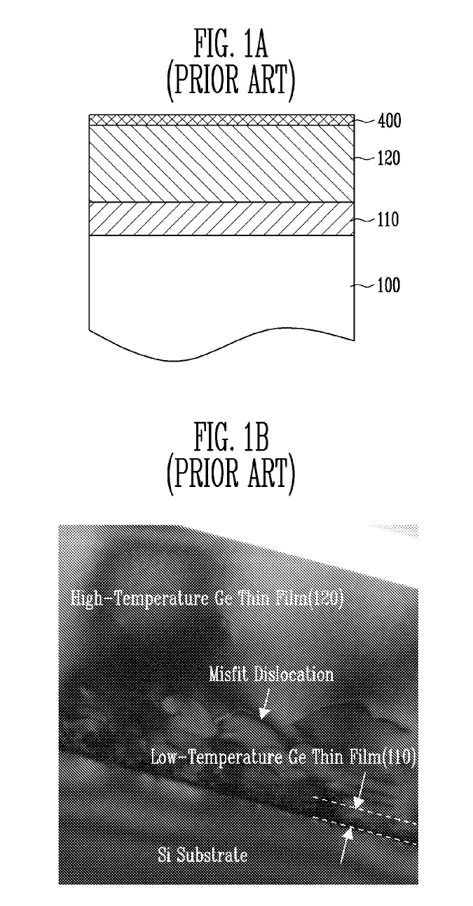

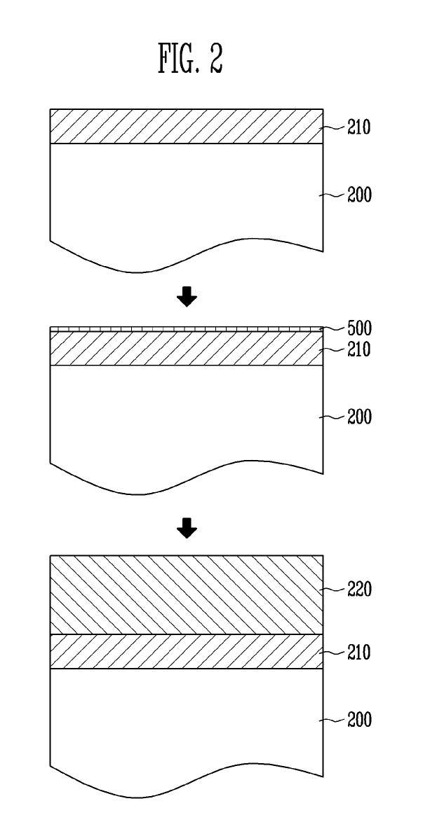

The Ge concentrations of the Ge single crystal thin film formed using RPCVD according to Example 1 and the conventional Ge thin film (shown in FIG. 1) formed using UHVCVD were obtained through SIMS analysis, and the result is shown in FIG. 5. As shown in FIG. 5, the conventional Ge thin film was changed into a Si—Ge layer whose thickness was ⅓ of the overall thickness. The Si—Ge layer was formed by interdiffusing silicon atoms into the Ge thin layer through long-time annealing at a high temperature to reduce threading dislocation density. The conventional long-time annealing is effective in reducing the threading dislocation density, but has problems of a change in band-gap according to the formation of the Si—Ge layer, and as shown in FIG. 1, propagation of misfit dislocation, while the method according to the present invention does not have such problems and is capable of growing a high-quality Ge single crystal thin film having low dislocation density.

Cross-Sectional Evaluation of Single Crystal Thin Film

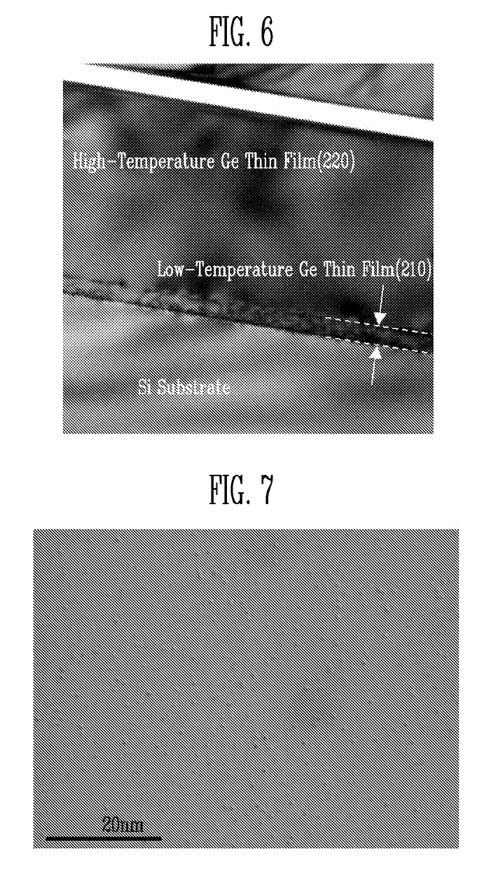

A cross-section of the Ge single crystal thin film formed using RPCVD according to Example 1 was photographed using a TEM microscope. The photograph is shown in FIG. 6.

It can be seen from the cross-sectional photograph in FIG. 6 that misfit dislocation was restrictively generated in the low-temperature Ge thin film without propagation over the low-temperature Ge thin film, and a single crystal thin film with low threading dislocation density on its surface and a smooth surface was grown, compared to FIG. 1B showing a cross-sectional photograph of the conventional Ge thin film.

Measurement of Threading Dislocation Density

FIG. 7 is an optical microscope photograph of a surface subjected to Secco-etching (the Ge single crystal thin film was dipped in a solution of 0.15M-K₂Cr₂O₇:HF:H₂O=1:2:30 at an atmospheric temperature for 1 minute) to measure the threading dislocation density of the Ge single crystal thin film formed using RPCVD according to Example 1. The Secco-etching was performed using the most common method of measuring threading dislocation density. The threading dislocation density of the Ge single crystal thin film according to Example 1 was 1.7×10⁷ cm⁻², which was almost the same as the dislocation density of the Ge thin film formed through long-time post-annealing using conventional UHVCVD.

According to the present invention, a Ge single crystal thin film having low dislocation density and a smooth surface is formed on a silicon substrate using RPCVD, and thus conventional problems resulting from long-time high temperature annealing, including silicon diffusion forming a Si—Ge layer and propagation of misfit dislocation to a high-temperature Ge thin film, can be overcome.

In the conventional art, low mass-productivity is caused by use of high-priced ultra-high vacuum equipment, and high production costs are necessitated by an additional long-time high temperature annealing process. The present invention, however, exhibits very high mass-productivity since a real-time annealing process is performed for a short period of time using RPCVD.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A method of growing a germanium (Ge) single crystal thin film with low threading dislocation density using reduced pressure chemical vapor deposition (RPCVD), comprising:
growing a Ge thin film on a silicon (Si) substrate at a low temperature;
performing real-time annealing for a short period of time; and
growing the annealed Ge thin film at a high temperature.

2. The method according to claim 1, further comprising growing a Si—Ge thin film after the real-time annealing and before growing the high-temperature Ge thin film.

3. The method according to claim 1, wherein the low-temperature Ge thin film is grown to a thickness of about 80 to about 120 nm under the conditions of a temperature of about 300 to about 500° C. and a pressure of about 30 to about 80 Torr.

4. The method according to claim 2, wherein the low-temperature Ge thin film is grown to a thickness of about 80 to about 120 nm under the conditions of a temperature of about 300 to about 500° C. and a pressure of about 30 to about 80 Torr.

5. The method according to claim 1, wherein the real-time annealing is performed for about 5 to about 20 minutes by stopping injection of a Ge source gas, injecting only a carrier gas, and increasing a temperature to about 850 to about 900° C. at a pressure of about 30 to about 80 Torr.

6. The method according to claim 2, wherein the real-time annealing is performed for about 5 to about 20 minutes by stopping injection of a Ge source gas, injecting only a carrier gas, and increasing a temperature to about 850 to about 900° C. at a pressure of about 30 to about 80 Torr.

7. The method according to claim 5, wherein the temperature increasing and decreasing rates are about 200° C. per minute.

8. The method according to claim 6, wherein the temperature increasing and decreasing rates are about 200° C. per minute.

9. The method according to claim 1, wherein the high-temperature Ge thin film is grown to a thickness of about 500 to about 1500 nm under the conditions of a temperature of about 600 to about 800° C. and a pressure of about 30 to about 80 Torr.

10. The method according to claim 2, wherein the high-temperature Ge thin film is grown to a thickness of about 500 to about 1500 nm under the conditions of a temperature of about 600 to about 800° C. and a pressure of about 30 to about 80 Torr.

11. The method according to claim 2, wherein the Si—Ge thin film is grown to a thickness of about 50 to about 100 nm under the conditions of a temperature of about 600 to about 650° C. and a pressure of about 30 to about 80 Torr.

12. The method according to claim 2, wherein while growing the Si—Ge thin film, the Ge content linearly increases from 80 to 85 at % to 100 at %.

13. The method according to claim 1, wherein the source gas used for the low- and high-temperature Ge thin films is GeH₄ gas diluted to 10 to 30 vol % with hydrogen gas, and the carrier gas is hydrogen gas.

14. The method according to claim 2, wherein the source gas used for the low- and high-temperature Ge thin films is GeH₄ gas diluted to 10 to 30 vol % with hydrogen gas, and the carrier gas is hydrogen gas.

15. The method according to claim 2, wherein the source gases used for the Si—Ge thin film are SiH₄ and GeH₄ gases, and the Ge content is controlled by a ratio of these gases.
